(19) United States
(12) Patent Application Publication
(10) Pub. No.: US 2015/0041687 A1
(43) Pub. Date: Feb. 12, 2015

(54) OPTICAL COUPLING DEVICE AND METHOD OF MANUFACTURING OPTICAL COUPLING DEVICE

(71) Applicant: Renesas Electronics Corporation, Kanagawa (JP)

(72) Inventor: Masaki MATSUDA, Kanagawa (JP)

(73) Assignee: Renesas Electronics Corporation, Kanagawa (JP)

(21) Appl. No.: 14/334,820

(22) Filed: Jul. 18, 2014

(30) Foreign Application Priority Data
Aug. 7, 2013 (JP) 2013-164214

(51) Int. Cl. H04B 10/80; H01L 25/16; H01L 25/00

(52) U.S. Cl. CPC H04B 10/802; H01L 25/50; H01L 25/167
USPC 250/551; 438/25

(57) ABSTRACT

A first sealing resin seals a space between a light emitting element and an insulating member, and a second sealing resin seals a space between a light receiving element and the insulating member. The first sealing resin includes a plurality of first particles having a refractive index higher than that of the first sealing resin. The content ratio of the first particles in the first sealing resin changes stepwise or continuously as the particles approach the insulating member from the light-emitting element. The content ratio of the first particles in the first sealing resin in a range up to 10 μm from the light emitting element is higher than the content ratio of the first particles in the first sealing resin in a range up to 10 μm from the insulating member.

This application is based on Japanese patent application No. 2013-164214, the content of which is incorporated hereinto by reference.

### BACKGROUND

1. Technical Field

The present invention relates to an optical coupling device and a method of manufacturing an optical coupling device, and to a technique applicable to an optical coupling device including, for example, a light emitting element and a light receiving element.

2. Related Art

One of devices that transmit a signal in a state where two circuits operating at different voltages are insulated from each other is an optical coupling device. The optical coupling device has a configuration in which a light emitting element and a light receiving element are sealed with a sealing resin.

Japanese Unexamined Patent Publication No. 2004-15063 discloses that first particles having a refractive index higher than that of a sealing resin and phosphor particles are mixed in the sealing resin that seals a light-emitting element. The diameter of the first particle is smaller than the wavelength of light emitted from the light-emitting element. In addition, by including the first particles, the refractive index of the sealing resin becomes substantially the same level as the refractive index of the phosphor particles.

In order to increase the accuracy of signal transmission from the light emitting element to the light receiving element, it is necessary to increase the amount of light reaching the light receiving element from the light-emitting element. The refractive index of a material constituting a light emission surface of the light emitting element is generally higher than the refractive index of the sealing resin. For this reason, the inventor has considered that a portion of light may be reflected between the light emitting element and the sealing resin, thus deteriorating light extraction efficiency. In order to prevent this, the refractive index of the sealing resin may only have to be increased.

On the other hand, in order to secure a dielectric withstand voltage between the light emitting element and the light receiving element, an insulating member is sometimes disposed between sealing resins. In this case, a portion of light is reflected between the sealing resin and the insulating member by simply increasing the refractive index of the sealing resin because a difference between the refractive index of the sealing resin and the refractive index of the insulating member increases. For this reason, it is difficult to increase the amount of light reaching the light receiving element from the light emitting element while securing a withstand voltage between the light emitting element and the light receiving element.

Other problems and novel features will be made clearer from the description and the accompanying drawings of the present specification.

### SUMMARY

In one embodiment, an insulating member is disposed between a light emitting element and a light receiving element. A space between the light emitting element and the insulating member is sealed with a first sealing resin, and a space between the light receiving element and the insulating member is sealed with a second sealing resin. The first sealing resin includes a plurality of first particles having a refractive index higher than that of the first sealing resin. A content ratio of the first particles in the first sealing resin changes stepwise or continuously as the particles approach the insulating member from the light emitting element. A content ratio of the first particles in the first sealing resin in a range up to 10 μm from the light emitting element is higher than a content ratio of the first particles in the first sealing resin in a range up to 10 μm from the insulating member.

In another embodiment, an insulating member is disposed between a light emitting element and a light receiving element. A space between the light emitting element and the insulating member is sealed with a first sealing resin, and a space between the light receiving element and the insulating member is sealed with a second sealing resin. The insulating member includes a first layer having a refractive index lower than those of the first sealing resin and the second sealing resin, and a second layer which is formed at a first surface facing the first sealing resin in the first layer, and of which a refractive index lies between those of the first sealing resin and the first layer.

According to the embodiment, it is possible to increase the amount of light reaching the light receiving element from the light emitting element while securing a withstand voltage between the light emitting element and the light receiving element.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating a configuration of an optical coupling device according to a first embodiment.

FIG. 2 is a diagram illustrating a configuration of a first sealing resin.

FIG. 3 is a diagram schematically illustrating an example of a change in refractive index from a light emitting element to a light receiving element.

FIG. 4 is a diagram illustrating a modified example of FIG. 3.

FIG. 5A is diagram illustrating a method of manufacturing an optical coupling device.

FIG. 5B is diagram illustrating a method of manufacturing an optical coupling device.

FIG. 5C is diagram illustrating a method of manufacturing an optical coupling device.

FIG. 5D is diagram illustrating a method of manufacturing an optical coupling device.

FIG. 6A is cross-sectional view illustrating a method of manufacturing an optical coupling device according to a second embodiment.

FIG. 6B is cross-sectional view illustrating a method of manufacturing an optical coupling device according to a second embodiment.

FIG. 6C is cross-sectional view illustrating a method of manufacturing an optical coupling device according to a second embodiment.

FIG. 6D is cross-sectional view illustrating a method of manufacturing an optical coupling device according to a second embodiment.

FIG. 6E is cross-sectional view illustrating a method of manufacturing an optical coupling device according to a second embodiment.

FIG. 7 is a diagram schematically illustrating a change in refractive index from the light emitting element to the light receiving element.

FIG. 8 is a diagram illustrating results obtained by simulating a relationship between the transmittance of light from the light emitting element to an insulating member and the angle of incidence of light from the light-emitting element on the first sealing resin.

FIG. 9A is diagram illustrating a change in refractive index in a comparative example.

FIG. 9B is diagram illustrating results obtained by simulating a relationship between the transmittance of light from the light emitting element to the insulating member and the angle of incidence of light from the light-emitting element on the first sealing resin, in a comparative example.

FIG. 10 is a diagram illustrating a configuration of an optical coupling device according to a third embodiment.

FIG. 11 is a diagram schematically illustrating a change in refractive index from the light emitting element to the light receiving element.

FIG. 12 is a diagram illustrating a configuration of an optical coupling device according to a fourth embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the present invention will be described with reference to the accompanying drawings. In all the drawings, like elements are referenced by like reference numerals and descriptions thereof will not be repeated.

### First Embodiment

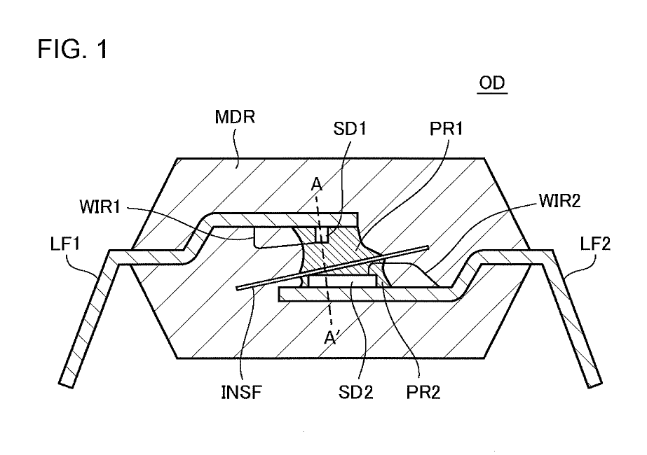

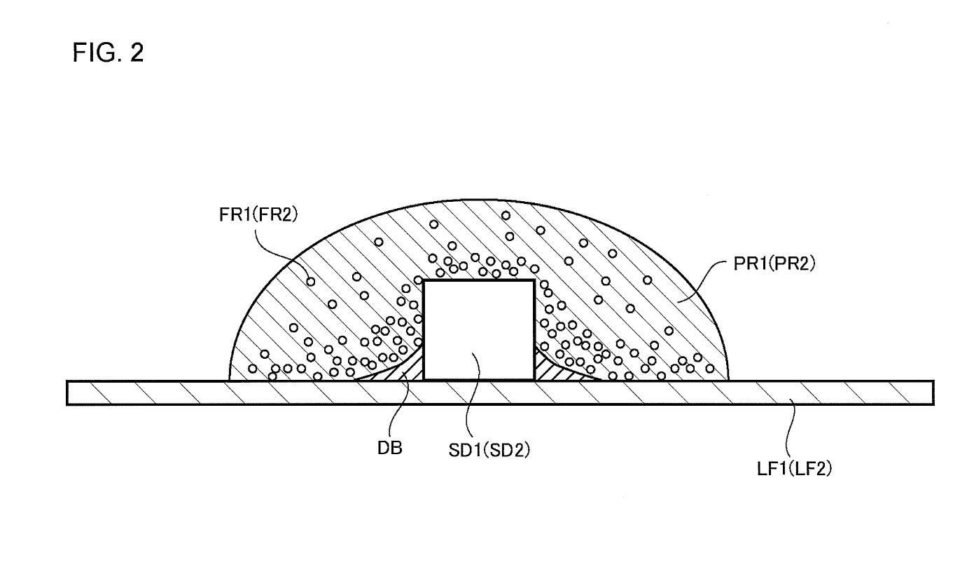

FIG. 1 is a cross-sectional view illustrating a configuration of an optical coupling device OD according to a first embodiment. The optical coupling device OD includes a light emitting element SD1, a light receiving element SD2, an insulating member INSF, a first sealing resin PR1, and a second sealing resin PR2. The light emitting element SD1 and the light receiving element SD2 face each other. The insulating member INSF is provided between the light emitting element SD1 and the light receiving element SD2, and transmits light emitted by the light emitting element SD1. The first sealing resin PR1 seals a space between the light emitting element SD1 and the insulating member INSF, and the second sealing resin PR2 seals a space between the light receiving element SD2 and the insulating member INSF. The first sealing resin PR1 includes a plurality of first particles FR1 (shown in FIG. 2) having a refractive index higher than that of the first sealing resin PR1. The content ratio of the first particles FR1 in the first sealing resin PR1 changes stepwise or continuously as the particles approach the insulating member INSF from the light emitting element SD1. The content ratio of the first particles FR1 in the first sealing resin PR1 in a range up to 10 μm from the light emitting element SD1 is higher than the content ratio of the first particles FR1 in the first sealing resin PR1 in a range up to 10 μm from the insulating member INSF. Hereinafter, a detailed description will be given.

The light emitting element SD1 is, for example, a Light Emitting Diode (LED) or a semiconductor laser, and is mounted onto a lead frame LF1. The light emitting element SD1 is electrically connected to the lead frame LF1 through a bonding wire WIR1. The light emitting element SD1 generates an optical signal by emitting light in accordance with a signal transmitted from the outside through the bonding wire WIR1. Meanwhile, the light emitting element SD1 is formed of a compound semiconductor such as GaAs. The refractive index of the compound semiconductor is, for example, equal to or greater than 3.0 and equal to or less than 5.0. In addition, a light emission layer of the light emitting element SD1 may be covered with a silicon nitride film (having a refractive index of approximately 2.0) or a silicon oxide film (having a refractive index of approximately 1.4).

The light receiving element SD2 is mounted onto a lead frame LF2, and is electrically connected to a lead frame LF2 through a bonding wire WIR2. The light receiving element SD2 includes a photoelectric conversion element. The light receiving element SD2 faces the light emitting element SD1, and thus receives an optical signal transmitted from the light emitting element SD1 to convert the received signal into an electrical signal. The electrical signal is transmitted to an external circuit through the bonding wire WIR2 and the lead frame LF2. The light receiving element SD2 is formed using, for example, Si. The refractive index of Si is 3.4 to 3.8. In addition, the surface layer of the light receiving element SD2 may be covered with a silicon nitride film or a silicon oxide film.

In order to increase insulation properties between the light emitting element SD1 and the light receiving element SD2, the insulating member INSF is disposed in a space between the light emitting element SD1 and the light receiving element SD2. In the example shown in this drawing, the insulating member INSF is, for example, an insulating film, and is formed of, for example, polyimide.

The space between the light emitting element SD1 and the insulating member INSF is sealed with the first sealing resin PR1, and the space between the light receiving element SD2 and the insulating member INSF is sealed with the second sealing resin PR2. The first sealing resin PR1 and the second sealing resin PR2 are, for example, silicone resins, and are formed using a potting method. The first sealing resin PR1 covers the light emitting element SD1, but does not cover a connection portion between the bonding wire WIR1 and the lead frame LF1. In addition, the second sealing resin PR2 covers the light receiving element SD2, but does not cover a connection portion between the bonding wire WIR2 and the lead frame LF2. The refractive indexes of the first sealing resin PR1 and the second sealing resin PR2 are, for example, equal to or greater than 1.2 and equal to or less than 1.6.

The first sealing resin PR1, the lead frame LF1, the bonding wire WIR1, the second sealing resin PR2, the lead frame LF2, the bonding wire WIR2, and the insulating member INSF are sealed with a sealing resin MDR. The sealing resin MDR is, for example, an epoxy resin. The sealing resin MDR is a non-light-transmitting resin, and suppresses the leakage of light from the first sealing resin PR1 and the second sealing resin PR2 and malfunction of the light receiving element SD2 due to the infiltration of light from the outside. Meanwhile, both the lead terminal of the lead frame LF1 and the lead terminal of the lead frame LF2 are not covered with the sealing resin MDR.

FIG. 2 is a diagram illustrating a configuration of the first sealing resin PR1. In this drawing, for the purpose of description, the shape of the first sealing resin PR1 is schematically illustrated, and the insulating member INSF is omitted. The light emitting element SD1 is fixed on the lead frame LF1 using a fixing layer DB. The fixing layer DB is a die bonding material, and is, for example, a silver paste. The first sealing resin PR1 seals a region located in the vicinity of the light emitting element SD1 in the light emitting element SD1 and the lead frame LF1.

The first sealing resin PR1 includes a plurality of first particles FR1. The diameter of the first particle FR1 is, for example, equal to or greater than 10 nm and equal to or less than 1 μm. The refractive index of the first particles FR1 is higher than the refractive index of the first sealing resin PR1. In addition, the density of the first particles FR1 is higher than the density of the first sealing resin PR1. The first particle FR1 may be at least one of, for example, zirconium oxide, hafnium oxide, gallium arsenide, and gallium phosphide, and the first particle FR1 may be a compound semiconductor (for example, gallium arsenide) constituting the light emitting element SD1. The content ratio of the first particles FR1 in the first sealing resin PR1 changes stepwise or continuously as the particles approach the insulating member INSF from the light emitting element SD1 (toward the upward direction in the example shown in this drawing). The content ratio of the first particles FR1 in the first sealing resin PR1 in a range up to 10 μm from the light emitting element SD1 is higher than the content ratio of the first particles FR1 in the first sealing resin PR1 in a range up to 10 μm from the insulating member INSF. Here, the content ratio of the first particles FR1 can be calculated as the ratio of an area occupied by the first particles FR1, for example, in a cross-sectional area generated by cutting away the first sealing resin PR1. In addition, the content ratio of the first particles FR1 in the first sealing resin PR1 is not always required to decrease or be constant as the particles approach the insulating member INSF from the light emitting element SD1, and may increase in some portions.

Meanwhile, similarly to the first sealing resin PR1 shown in FIG. 2, the second sealing resin PR2 may include a plurality of second particles FR2. The size and material of the second particle FR2 are the same as those in, for example, the first sealing resin PR1. The refractive index of the second particles FR2 is higher than the refractive index of the second sealing resin PR2. In addition, the density of the second particles FR2 is higher than the density of the second sealing resin PR2. The content ratio of the second particles FR2 in the second sealing resin PR2 changes stepwise or continuously as the particles approach the insulating member INSF from the light receiving element SD2. The content ratio of the second particles FR2 in the second sealing resin PR2 in a range up to 10 μm from the light receiving element SD2 is higher than the content ratio of the second particles FR2 in the second sealing resin PR2 in a range up to 10 μm from the insulating member INSF. Here, the content ratio of the second particles FR2 in the second sealing resin PR2 can also be calculated by a method similar to that for the content ratio of the first particles FR1 in the first sealing resin PR1. In addition, the content ratio of the second particles FR2 is not always required to decrease or be constant as the particles approach the insulating member INSF from the light receiving element SD2, and may increase in some portions.

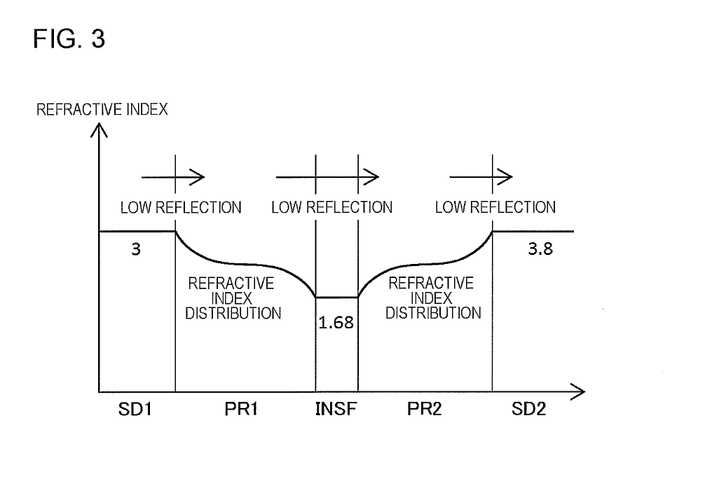

FIG. 3 is a diagram schematically illustrating an example of a change in refractive index from the light emitting element SD1 to the light receiving element SD2. The material constituting the light emitting element SD1 has a refractive index higher than the material constituting the insulating member INSF, but the refractive index of the first sealing resin PR1 located therebetween decreases gradually as the sealing resin approaches the insulating member INSF from the light emitting element SD1. This is because in the inside of the first sealing resin PR1, the content ratio of the first particles FR1 changes.

Similarly, the material constituting the light receiving element SD2 has a refractive index higher than the material constituting the insulating member INSF, but the refractive index of the second sealing resin PR2 located therebetween decreases gradually as the sealing resin approaches the insulating member INSF from the light receiving element SD2. This is because in the inside of the second sealing resin PR2, the content ratio of the second particles FR2 changes.

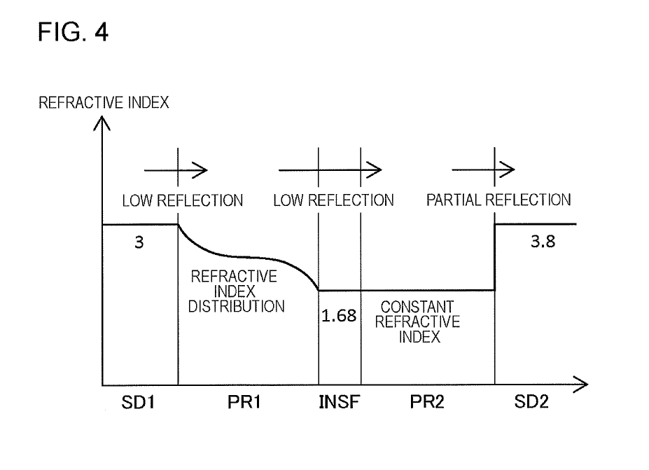

Meanwhile, when the second sealing resin PR2 does not include the second particle FR2, as shown in FIG. 4, the refractive index almost does not change or lowers a little at a boundary between the insulating member INSF and the second sealing resin PR2. The refractive index rises at a boundary between the second sealing resin PR2 and the light receiving element SD2.

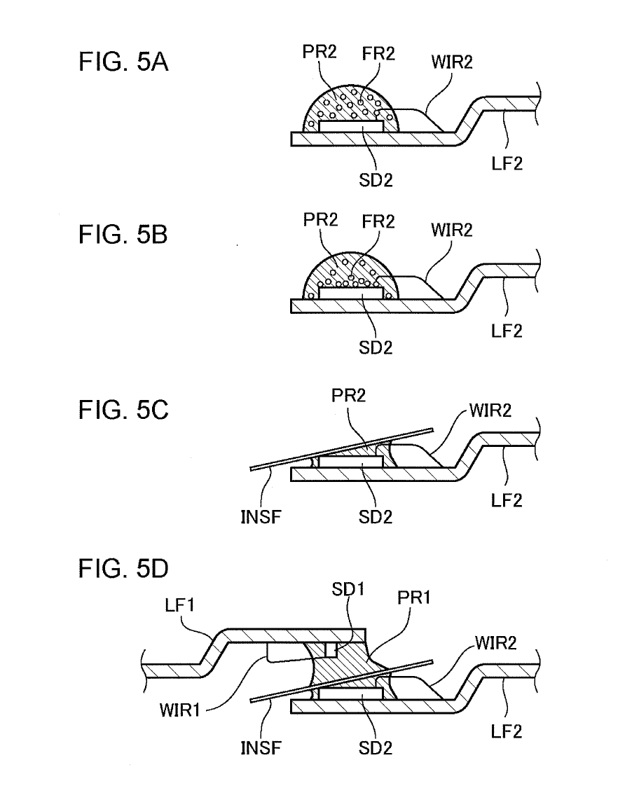

FIGS. 5A to 5D are diagrams illustrating a method of manufacturing the optical coupling device OD according to the present embodiment. First, as shown in FIG. 5A, the light receiving element SD2 is fixed onto the lead frame LF2 using the fixing layer DB. The light receiving element SD2 and the lead frame LF2 are connected to each other using the bonding wire WIR2. The second sealing resin PR2 is dropped on the lead frame LF2 and on the light receiving element SD2. At this stage, the second particles FR2 are included in the second sealing resin PR2.

Before the second sealing resin PR2 is cured, the lead frame LF2, the light receiving element SD2, the bonding wire WIR2, and the second sealing resin PR2 are left to stand for a predetermined time. This standing time is, for example, equal to or greater than one hour and equal to or less than twenty-four hours. Thereby, as shown in FIG. 5B, the second particles FR2 included in the second sealing resin PR2 settle due to gravity, and gain a distribution biased toward the light receiving element SD2 side in the second sealing resin PR2. Consequently, the content ratio of the second particles FR2 in the second sealing resin PR2 decreases gradually as the particles approach the insulating member INSF from the light receiving element SD2. Meanwhile, in this case, a centrifugal force may be applied to the lead frame LF2, the light receiving element SD2, the bonding wire WIR2, and the second sealing resin PR2. In this case, it is possible to shorten a time until the second particles FR2 included in the second sealing resin PR2 settle.

Thereafter, as shown in FIG. 5C, the insulating member INSF is disposed on the second sealing resin PR2 which is uncured, and then the second sealing resin PR2 is cured.

The light emitting element SD1 is fixed onto the lead frame LF1 using the fixing layer DB. The light emitting element SD1 and the lead frame LF1 are connected to each other using the bonding wire WIR1. The first sealing resin PR1 is dropped on the lead frame LF1 and on the light emitting element SD1. In this step, the first particles FR1 are included in the first sealing resin PR1.

Before the first sealing resin PR1 is cured, the first particles FR1 gain a distribution biased toward the light emitting element SD1 side in the first sealing resin PR1. Such a method is the same as the method of biasing the second particles FR2 within the second sealing resin PR2. Consequently, the content ratio of the first particles FR1 in the first sealing resin PR1 decreases gradually as the particles approach the insulating member INSF from the light emitting element SD1.

Thereafter, as shown in FIG. 5D, the light emitting element SD1 is caused to face the light receiving element SD2, and the upper surface of the first sealing resin PR1 is brought into contact with the insulating member INSF. In this state, the first sealing resin PR1 is cured.

Thereafter, the sealing resin MDR is formed. in this manner, the optical coupling device OD shown in FIG. 1 is formed.

Meanwhile, in the above-mentioned process, the light emitting element SD1 and the light receiving element SD2 may be switched.

As described above, according to the present embodiment, the content ratio of the first particles FR1 in the first sealing resin PR1 changes stepwise or continuously as the particles approach the insulating member INSF from the light emitting element SD1. The content ratio of the first particles FR1 in the first sealing resin PR1 in a range up to 10 μm from the light emitting element SD1 is higher than the content ratio of the first particles FR1 in the first sealing resin PR1 in a range up to 10 μm from the insulating member INSF. For this reason, the refractive index of the first sealing resin PR1 decreases gradually as the sealing resin approaches the insulating member INSF from the light emitting element SD1. For this reason, a difference in refractive index at an interface between the light emitting element SD1 and the first sealing resin PR1 and a difference in refractive index at an interface between the first sealing resin PR1 and the insulating member INSF are reduced. Therefore, when light is emitted from the light emitting element SD1 to the first sealing resin PR1, it is possible to suppress the reflection of the light at these interfaces. In addition, when light is incident on the insulating member INSF from the first sealing resin PR1, it is possible to suppress the reflection of the light at these interfaces. For this reason, it is possible to increase the amount of light reaching the light receiving element SD2 from the light emitting element SD1 while securing a withstand voltage between the light emitting element SD1 and the light receiving element SD2.

In addition, the content ratio of the second particles FR2 in the second sealing resin PR2 changes stepwise or continuously as the particles approach the insulating member INSF from the light receiving element SD2. The content ratio of the second particles FR2 in the second sealing resin PR2 in a range up to 10 μm from the light receiving element SD2 is higher than the content ratio of the second particles FR2 in the second sealing resin PR2 in a range up to 10 μm from the insulating member INSF. For this reason, the refractive index of the second sealing resin PR2 increases gradually as the sealing resin approaches the light receiving element SD2 from the insulating member INSF. For this reason, a difference in refractive index at an interface between the insulating member INSF and the second sealing resin PR2 and a difference in refractive index at an interface between the second sealing resin PR2 and the light receiving element SD2 are reduced. Therefore, when light is incident on the second sealing resin PR2 from the insulating member INSF, it is possible to suppress the reflection of the light at these interfaces. In addition, when light is incident on the light receiving element SD2 from the second sealing resin PR2, it is possible to suppress the reflection of the light at these interfaces. Therefore, it is possible to further increase the amount of light reaching the light receiving element from the light-emitting element.

### Second Embodiment

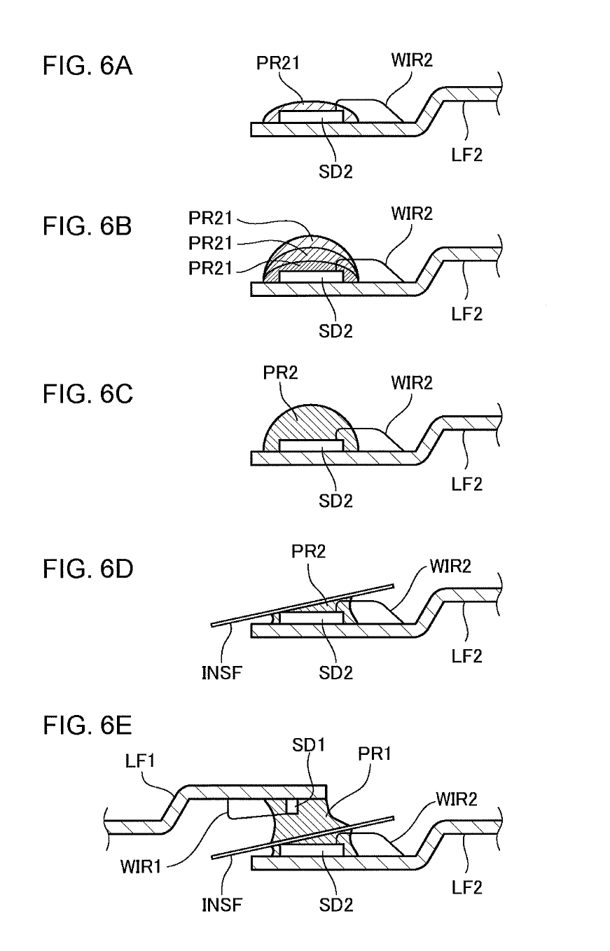

FIGS. 6A to 6E are cross-sectional views illustrating a method of manufacturing an optical coupling device OD according to a second embodiment. First, as shown in FIG. 6A, the light receiving element SD2 is fixed onto the lead frame LF2 using the fixing layer DB. The light receiving element SD2 and the lead frame LF2 are connected to each other using the bonding wire WIR2. A resin serving as a first layer PR21 of the second sealing resin PR2 is dropped on the lead frame LF2 and on the light receiving element SD2.

Next, as shown in FIG. 6B, at least one layer serving as the second sealing resin PR2 is applied (dropped) onto the first layer PR21. In this case, with an increasing number of upper layers, the content ratio of the second particles FR2 included in a resin lowers. That is, in the present embodiment, a process of disposing the second sealing resin PR2 which is not cured on the light receiving element SD2 is repeatedly performed while reducing the content ratio of the second particles FR2. In this manner, the second sealing resin PR2 is formed. In the example shown in this drawing, the second sealing resin PR2 is formed of three resin layers. However, the second sealing resin PR2 may be formed of four or more resin layers. Meanwhile, it is preferable that the thickness of each layer be more than 10 times the peak wavelength of light emitted from the light emitting element SD1. This results in an improvement in effects described later.

Thereafter, as shown in FIG. 6C, the application of ultrasonic vibration to the second sealing resin PR2, or the like is performed, and thus mutual diffusion is given rise to at a boundary between each resin layer. Thereby, a boundary between each resin layer in the second sealing resin PR2 disappears (that is, there is a continuous change in refractive index), or a difference in the content ratio of the second particles FR2 (that is, difference in refractive index) at a boundary between each resin layer is reduced.

Subsequent processes are the same as the processes shown in FIGS. 5C and 5D (FIGS. 6D and 6E). Meanwhile, in the above-mentioned processes, the light emitting element SD1 side and the light receiving element SD2 side may be reversed.

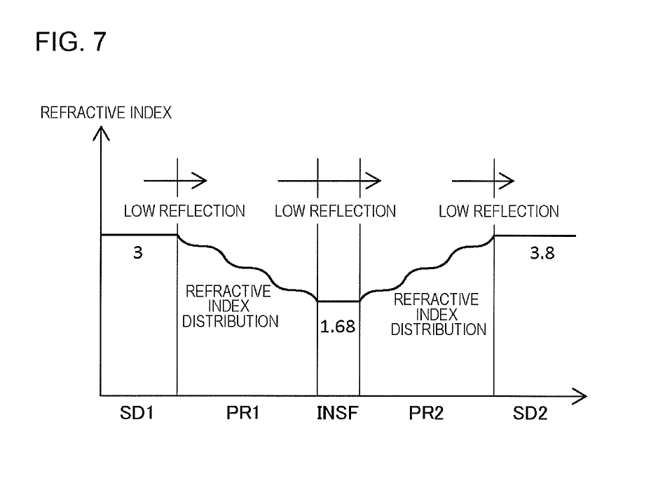

FIG. 7 is a diagram illustrating a change in refractive index from the light emitting element SD1 to the light receiving element SD2 in the present embodiment. As described above, both the first sealing resin PR1 and the second sealing resin PR2 are formed by overlapping a plurality of layers (preferably, three or more layers).

The refractive index of the first sealing resin PR1 decreases stepwise as the sealing resin approaches the insulating member INSF from the light emitting element SD1. This is because in the inside of the first sealing resin PR1, the content ratio of the first particles FR1 changes stepwise. However, the refractive index changes smoothly at a boundary of each layer.

In addition, the refractive index of the second sealing resin PR2 also decreases stepwise as the sealing resin approaches the insulating member INSF from the light receiving element SD2. This is also because in the inside of the second sealing resin PR2, the content ratio of the second particles FR2 changes stepwise. However, the refractive index changes smoothly at a boundary of each layer.

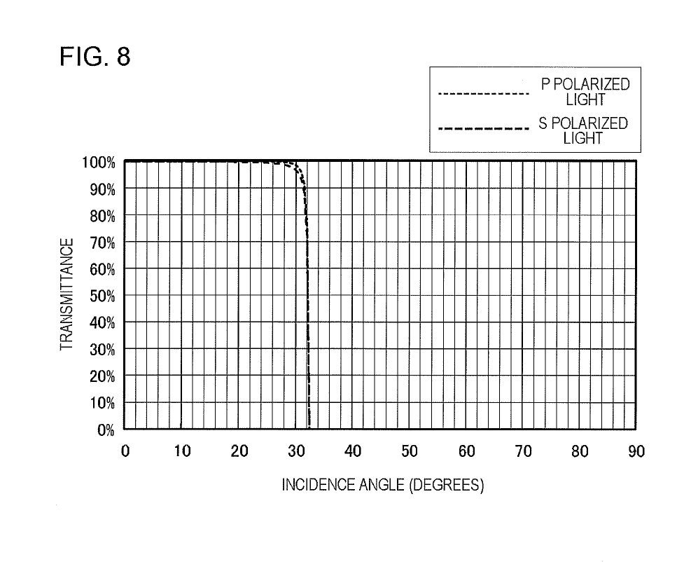

FIG. 8 is a diagram illustrating results obtained by simulating a relationship between the transmittance of light from the light emitting element SD1 to the insulating member INSF and the angle of incidence of light from the light emitting element SD1 on the first sealing resin PR1. In the simulation, the refractive index of the light emitting element SD1 was set to 3, and the refractive index of the insulating member INSF was set to 1.6. In addition, the first sealing resin PR1 was formed of thirteen resin layers, and the refractive index of each layer was changed by 0.1.

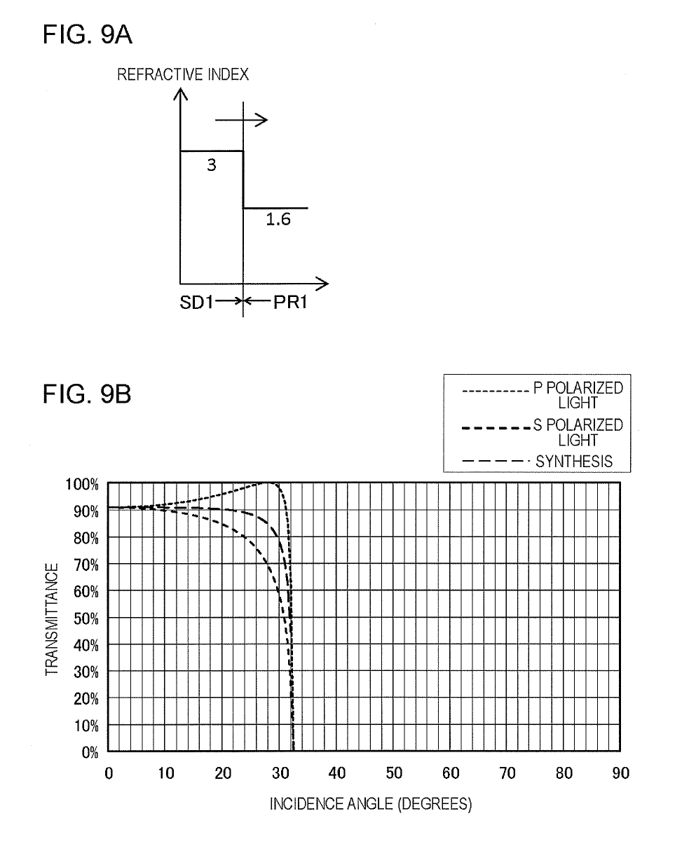

FIGS. 9A and 9B are diagram illustrating results obtained by simulating a relationship between the transmittance of light from the light emitting element SD1 to the insulating member INSF and the angle of incidence of light from the light emitting element SD1 on the first sealing resin PR1, in a comparative example. The conditions of the simulation in the comparative example are the same as the conditions shown in FIG. 8, except that the first sealing resin PR1 is formed to have a one-layer structure, and that the refractive index is set to 1.6.

In the examples shown in FIGS. 9A and 9B, when the incidence angle of light exceeds 10 degrees, the transmittance of light lowers gradually. On the other hand, in the example shown in FIG. 8, the transmittance of light remains close to 100% as the incidence angle of light comes close to 32 degrees which is a critical angle. From this result, according to the present embodiment, it can be understood that the transmittance of light from the light emitting element SD1 to the insulating member INSF increases. In a path of light from the insulating member INSF to the light receiving element SD2, the same effect is obtained as well.

### Third Embodiment

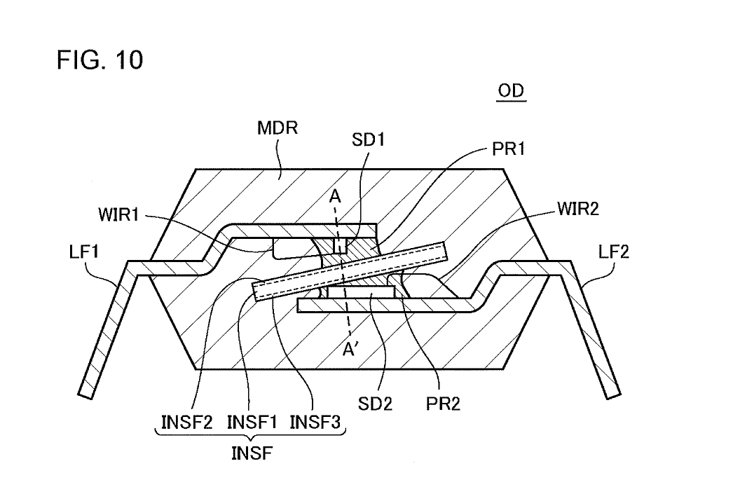

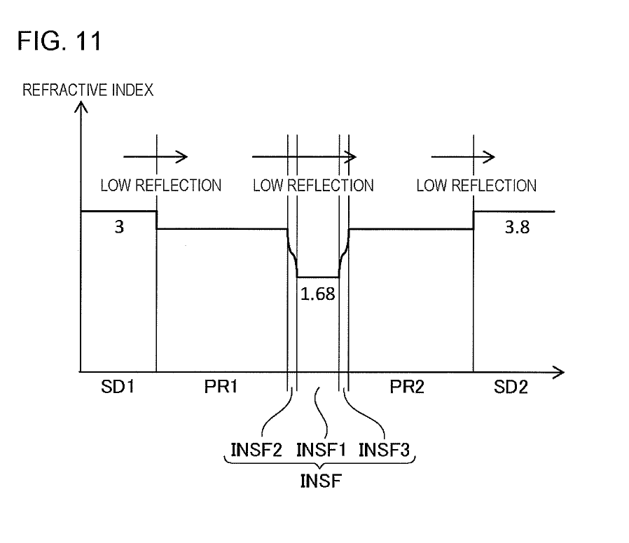

FIG. 10 is a diagram illustrating a configuration of an optical coupling device OD according to a third embodiment. FIG. 11 is a diagram schematically illustrating a change in refractive index from the light emitting element SD1 to the light receiving element SD2. The optical coupling device OD according to the present embodiment has the same configuration as that of the optical coupling device OD according to the first embodiment, except for the following points.

First, the first sealing resin PR1 contains the first particles FR1 substantially uniformly as a whole, and the second sealing resin PR2 also contains the second particles FR2 substantially uniformly as a whole. For this reason, as shown in FIG. 11, the refractive indexes of the first sealing resin PR1 and the second sealing resin PR2 are high, and come close to the refractive indexes of the light emitting element SD1 and the light receiving element SD2, respectively. Thereby, the transmittance of light increases when the light is incident on the first sealing resin PR1 from the light emitting element SD1, and the transmittance of light increases when the light is incident on the light receiving element SD2 from the second sealing resin PR2.

The insulating member INSF includes a low refractive index layer INSL1 (first layer), a transition layer INSL2 (second layer), and a transition layer INSL3.

Specifically, the transition layer INSL2 is formed at a surface (first surface) on the first sealing resin PR1 side in the low refractive index layer INSL1, and the transition layer INSL3 is formed at a surface (second surface) on the second sealing resin PR2 side in the low refractive index layer INSL1. The refractive index of the transition layer INSL2 is between the refractive index of the first sealing resin PR1 and the refractive index of the low refractive index layer INSL1. Thereby, the transmittance of light increases when the light is incident on the insulating member INSF from the first sealing resin PR1. In addition, the refractive index of the transition layer INSL3 is between the refractive index of the second sealing resin PR2 and the refractive index of the low refractive index layer INSL1. Thereby, the transmittance of light increases when the light is incident on the second sealing resin PR2 from the insulating member INSF.

It is preferable that the refractive index of the transition layer INSL2 decrease stepwise or continuously from the surface on the first sealing resin PR1 side toward the surface on the low refractive index layer INSL1 side. This results in a further increase in the transmittance of light when the light is incident on the insulating member INSF from the first sealing resin PR1. In addition, it is preferable that the refractive index of the transition layer INSL3 also decrease stepwise or continuously from the surface on the second sealing resin PR2 side toward the surface on the low refractive index layer INSL1 side. This results in a further increase in the transmittance of light when the light is incident on the second sealing resin PR2 from the insulating member INSF.

Such an insulating member INSF is formed, for example, by applying the transition layers INSL2 and INSL3 onto the low refractive index layer INSL1.

Meanwhile, the insulating member INSF may not include the transition layer INSL3.

In the present embodiment, since the insulating member INSF is provided between the light emitting element SD1 and the light receiving element SD2, it is also possible to secure a withstand voltage between the light emitting element SD1 and the light receiving element SD2. In addition, since the transition layer INSL2 and the transition layer INSL3 are provided in the insulating member INSF, it is possible to increase the amount of light reaching the light receiving element SD2 from the light emitting element SD1.

### Fourth Embodiment

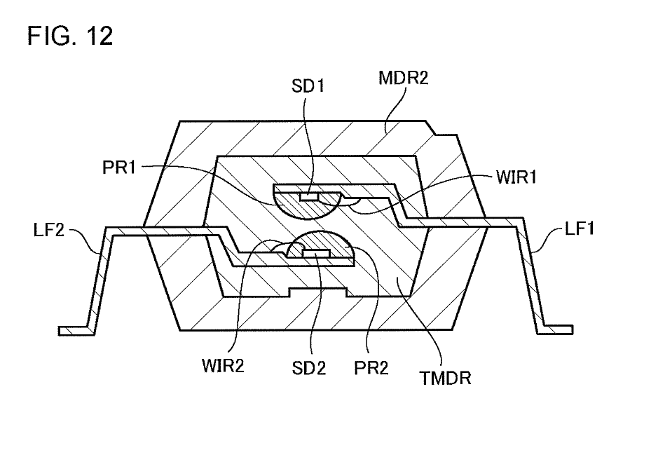

FIG. 12 is a diagram illustrating a configuration of an optical coupling device OD according to a fourth embodiment. The optical coupling device OD according to the present embodiment has the same configuration as that of the optical coupling device OD according to the first or second embodiment, except for the following points.

First, the insulating member INSF is not disposed between the first sealing resin PR1 and the second sealing resin PR2. Instead thereof, a light-transmitting sealing resin TMDR (insulating resin layer) is located between the first sealing resin PR1 and the second sealing resin PR2.

Meanwhile, in the example shown in this drawing, the periphery of the light-transmitting sealing resin TMDR is further covered with a non-light-transmitting sealing resin MDR2. As is the case with the first embodiment, the sealing resin MDR2 is a non-light-transmitting resin. For this reason, it is possible to suppress the leakage of light from the light-transmitting sealing resin TMDR to the sealing resin MDR2, and the malfunction of the light receiving element SD2 due to the infiltration of light from the outside.

In the present embodiment, since the light-transmitting sealing resin TMDR is provided between the light emitting element SD1 and the light receiving element SD2, it is also possible to secure a withstand voltage between the light emitting element SD1 and the light receiving element SD2. In addition, since the first sealing resin PR1 and the second sealing resin PR2 have the same configurations as those of the first or second embodiment, it is possible to increase the amount of light reaching the light receiving element SD2 from the light emitting element SD1.

As stated above, while the present invention devised by the inventor has been described specifically based on the embodiments thereof, the present invention is not limited to the above-mentioned embodiments, and it goes without saying that various changes and modifications may be made without departing from the scope of the invention.

It is apparent that the present invention is not limited to the above embodiment, and may be modified and changed without departing from the scope and spirit of the invention.

What is claimed is:

1. An optical coupling device comprising:
a light-emitting element;
a light receiving element that faces the light-emitting element;
an insulating member, provided between the light emitting element and the light receiving element, which transmits light emitted by the light-emitting element;
a first sealing resin that seals a space between the light emitting element and the insulating member; and
a second sealing resin that seals a space between the light receiving element and the insulating member,
wherein the first sealing resin includes a plurality of first particles having a refractive index higher than that of the first sealing resin,
a content ratio of the first particles in the first sealing resin changes stepwise or continuously as the particles approach the insulating member from the light-emitting element, and
a content ratio of the first particles in the first sealing resin in a range up to 10 μm from the light emitting element is higher than a content ratio of the first particles in the first sealing resin in a range up to 10 μm from the insulating member.

2. The optical coupling device according to claim 1, wherein the content ratio of the first particles in the first sealing resin changes in three or more steps as the particles approach the insulating member from the light-emitting element.

3. The optical coupling device according to claim 1, wherein the first sealing resin is a silicone resin, and
the first particle is at least one of zirconium oxide, hafnium oxide, gallium arsenide, and gallium phosphide.

4. The optical coupling device according to claim 1, wherein the insulating member is an insulating film.

5. The optical coupling device according to claim 1, wherein the insulating member is an insulating resin layer.

6. The optical coupling device according to claim 1, wherein the second sealing resin includes a plurality of second particles having a refractive index higher than that of the second sealing resin,
a content ratio of the second particles in the second sealing resin changes stepwise or continuously as the particles approach the insulating member from the light receiving element, and
a content ratio of the second particles in the second sealing resin in a range up to 10 μm from the light receiving element is higher than a content ratio of the second particles in the second sealing resin in a range up to 10 μm from the insulating member.

7. An optical coupling device comprising:
a light-emitting element;
a light receiving element that faces the light-emitting element;
an insulating member, provided between the light emitting element and the light receiving element, which transmits light emitted by the light-emitting element;
a first sealing resin that seals a space between the light emitting element and the insulating member; and
a second sealing resin that seals a space between the light receiving element and the insulating member,
wherein the insulating member includes
a first layer having a refractive index lower than those of the first sealing resin and the second sealing resin, and
a second layer which is formed at a first surface facing the first sealing resin in the first layer, and of which a refractive index lies between those of the first sealing resin and the first layer.

8. The optical coupling device according to claim 7, wherein the refractive index of the second layer decreases stepwise or continuously from a surface on the first sealing resin layer side toward a surface on the first layer side.

9. A method of manufacturing an optical coupling device, comprising:
sealing a light emitting element with a first sealing resin;
sealing a light receiving element with a second sealing resin; and
bonding the first sealing resin and the second sealing resin through an insulating member that transmits light which is emitted by the light-emitting element,
wherein the first sealing resin includes a plurality of first particles having a refractive index higher than that of the first sealing resin, and
the step of sealing the light emitting element with the first sealing resin includes
disposing the first sealing resin, which includes the plurality of first particles and is not cured, over the light-emitting element,
making a distribution of the first particles be biased toward the light emitting element side in the first sealing resin by causing gravity or a centrifugal force to act on the first sealing resin located over the light-emitting element, and
curing the first sealing resin.

10. A method of manufacturing an optical coupling device, comprising:
sealing a light emitting element with a first sealing resin;
sealing a light receiving element with a second sealing resin; and
bonding the first sealing resin and the second sealing resin through an insulating member that transmits light which is emitted by the light-emitting element,
wherein the first sealing resin includes a plurality of first particles having a refractive index higher than that of the first sealing resin, and
in the step of sealing the light emitting element with the first sealing resin, a step of disposing the first sealing resin, which includes the plurality of first particles and is not cured, over the light emitting element is repeatedly performed while reducing a content ratio of the plurality of first particles in the first sealing resin.
